(19) United States
(12) Patent Application Publication
(10) Pub. No.: US 2010/0007014 A1
(43) Pub. Date: Jan. 14, 2010

(54) SEMICONDUCTOR DEVICE

(75) Inventors: Hidetoshi Suzuki, Kawasaki-shi (JP); Isao Ozawa, Chigasaki-shi (JP); Atsushi Kaneko, Yokohama-shi (JP); Yuka Matsunaga, Yokohama-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/497,045

(22) Filed: Jul. 2, 2009

(30) Foreign Application Priority Data
Jul. 11, 2008 (JP) 2008-182086

(51) Int. Cl. H01L 25/065

(52) U.S. Cl. 257/723; 257/777; 257/E25.01

(57) ABSTRACT

According to an aspect of the invention, a semiconductor device includes: a semiconductor substrate; a memory chip disposed on the semiconductor substrate, the memory chip including: a first face that is not opposed to the semiconductor substrate; and a plurality of first pads disposed on the first face so that the first pads are aligned along a virtual line passing at a central portion on the first face; a controller chip disposed on the first face not to cover the first pads, the controller chip including: a second face that is not opposed to the first face; and a plurality of second pads disposed on the second face so that the second pads are aligned along at least one side of the second face; and a plurality of metal wires electrically connecting the first pads and the second pads.

### CROSS-REFERENCE TO RELATED APPLICATIONS

This application is based upon and claims the benefit of priority from Japanese Patent Application No. 2008-182086, filed Jul. 11, 2008, the entire contents of which are incorporated herein by reference.

### BACKGROUND

1. Field

The present invention relates to a semiconductor device, and more particularly, to a semiconductor device in which plural memory chips are mounted on a substrate.

2. Description of the Related Art

In a semiconductor memory card described in JP-A-2007-4775, openings not coated with solder resist are formed in some regions of an outer peripheral edge of a substrate and molding resin enters the openings to bring the molding resin into direct contact with the substrate, thereby enhancing the bonding force between the substrate and the molding resin.

In a semiconductor device described in JP-A-2007-129182, since a chip has a one-sided pad configuration in which pads are intensively arranged along one side of an element forming surface of the chip, drawings of wires between the pads and peripheral circuits are streamlined, thereby reducing a chip area.

### SUMMARY OF THE INVENTION

According to an aspect of the present invention, there is provided a semiconductor device including: a semiconductor substrate; a memory chip disposed on the semiconductor substrate, the memory chip including: a first face that is not opposed to the semiconductor substrate; and a plurality of first pads disposed on the first face so that the first pads are aligned along a virtual line passing at a central portion on the first face; a controller chip disposed on the first face not to cover the first pads, the controller chip including: a second face that is not opposed to the first face; and a plurality of second pads disposed on the second face so that the second pads are aligned along at least one side of the second face; and a plurality of metal wires electrically connecting the first pads and the second pads.

According to another aspect of the present invention, there is provided a semiconductor device including: a semiconductor substrate; a memory chip disposed on the semiconductor substrate, the memory chip including: a first memory cell array; a second memory cell array; and a peripheral circuit formed between the first memory cell array and the second memory cell array, the peripheral circuit being configured to control the first memory cell and the second memory cell; a plurality of first pads formed on the semiconductor substrate so that the first pads are aligned along the first memory cell array; a plurality of second pads formed on the memory chip so that the second pads are aligned along the first pads; a wiring layer formed on the memory chip, the wiring layer having a wiring pattern to electrically connect the second pads and the peripheral circuit; and a plurality of metal wires electrically connecting the first pads and the second pads.

According to another aspect of the present invention, there is provided a semiconductor device including: a semiconductor substrate; a memory chip disposed on the semiconductor substrate, the memory chip including: a first memory cell array; a second memory cell array; a decoder circuit formed between the first memory cell array and the second memory cell array, the decoder circuit includes peripheral circuit for controlling the first memory cell and the second memory cell; and an input circuit disposed along the decoder circuit, the first memory cell, and the second memory cell, the input circuit controlling an input signal to the decoder circuit, the first memory cell, and the second memory cell; a plurality of pads formed on the semiconductor substrate so that the pads are aligned along the input circuit; and a plurality of metal wires electrically connecting the pads and the input circuit.

According to another aspect of the present invention, there is provided a semiconductor device including: a printed circuit board having a connection portion formed on a mounting face of the printed circuit; a plurality of bumps disposed on the mounting surface; a first memory chip having a first face and a second face, the first face being bonded to the bumps; a second memory chip having a third face and a fourth face, the third face being bonded to the second face; a controller chip having a fifth face and a sixth face, the fifth face being bonded to the fourth face; and a metal wire electrically connecting the connection portion and the controller chip.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is a plan view illustrating a chip layout of a NAND flash memory according to a first embodiment.

FIG. 2 is a sectional view illustrating a chip layout in a package constituting the NAND flash memory according to the first embodiment.

FIGS. 3A and 3B are plan views illustrating another chip layout of the NAND flash memory according to the first embodiment.

FIGS. 4A and 4B are plan views illustrating another chip layout of the NAND flash memory according to the first embodiment.

FIG. 5 is a plan view illustrating another chip layout of the NAND flash memory according to the first embodiment.

FIG. 6 is a plan view illustrating another chip layout of the NAND flash memory according to the first embodiment.

FIG. 7 is a sectional view illustrating another chip layout in the package constituting the NAND flash memory according to the first embodiment.

FIGS. 8A and 8B are plan views illustrating an example of the chip layer of the NAND flash memory shown in FIG. 7.

FIGS. 9A and 9B are plan views illustrating another chip layout of the NAND flash memory according to the first embodiment.

FIGS. 10A and 10B are plan views illustrating another chip layout of the NAND flash memory according to the first embodiment.

FIGS. 11A and 11B are plan views illustrating another chip layout of the NAND flash memory according to the first embodiment.

FIG. 12 is a plan view illustrating a chip layout of a NAND flash memory according to a second embodiment.

FIG. 13 is a sectional view taken along line A-B of FIG. 12.

FIG. 14 is a plan view illustrating a chip layout of a NAND flash memory according to a third embodiment.

FIG. 15 is a sectional view illustrating a chip layout of a NAND flash memory according to a fourth embodiment.

FIG. 16 is a sectional view illustrating a chip layout of a NAND flash memory according to a fifth embodiment.

FIG. 17 is an enlarged sectional view illustrating a connection of a bonding wire and a contact plug in a NAND flash memory according to the fifth embodiment.

### DETAILED DESCRIPTION

Hereinafter, embodiments of the invention will be described with reference to the accompanying drawings. Here, a NAND flash memory is described as an example of a semiconductor device according to the embodiments. In the embodiments, like elements are referenced by like reference numerals and repeated description of the embodiments is omitted.

### First Embodiment

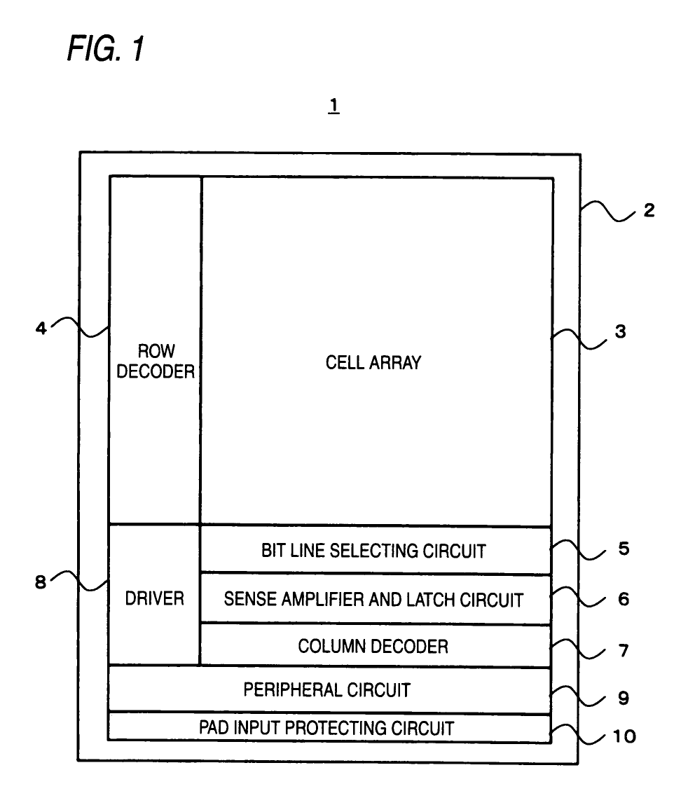

FIG. 1 is a plan view illustrating an example of a chip layout of a NAND flash memory 1. In the NAND flash memory 1 shown in FIG. 1, a cell array 3, a row decoder 4, a bit line selecting circuit 5, a sense amplifier and latch circuit 6, a column decoder 7, a driver 8, a peripheral circuit 9, and a pad input protecting circuit 10 are disposed on a semiconductor substrate 2. In the NAND flash memory 1 shown in FIG. 1, the cell array 3 has plural nonvolatile memory cells arranged in a matrix. The layout of the row decoder 4, the bit line selecting circuit 5, the sense amplifier and latch circuit 6, the column decoder 7, the driver 8, the peripheral circuit 9, and the pad input protecting circuit 10 is determined depending on a circuit configuration (arrangement of bit lines or word lines or the like) in the cell array 3.

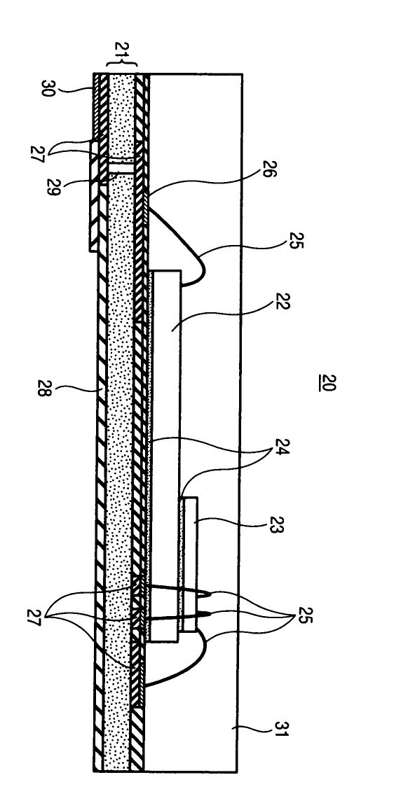

FIG. 2 is a sectional view illustrating an example of an inner configuration of the NAND flash memory 20 mounted with a NAND memory chip. In the NAND flash memory 20 shown in FIG. 2, a NAND memory chip 22 is bonded onto a chip mounting surface of the a printed circuit board 21 with an adhesive 24 and a controller chip 23 is bonded onto the surface of the NAND memory chip 22 with an adhesive 24. A solder resist 28 is applied to a chip mounting surface (top surface) and a chip non-mounting surface (bottom surface) of the printed circuit board 21 and bonding terminal plates 26 are formed therein. The bonding terminal plates 26 are electrically connected to pads (not shown) formed on the surface of the NAND memory chip 22 and the surface of the control chip 23 by bonding wires 25. External terminal plates 30 are formed in the left end portion of the bottom surface of the printed circuit board 21 in the drawing. Copper wires 27 are formed in the lower layer of the bonding terminal plates 26 and the upper layer of the external terminal plates 30. The copper wires 27 formed on the left side of the printed circuit board 21 in the drawing are connected to each other through through-holes 29 to electrically connect the pads of the NAND memory chip 22 to the external terminal plates 30. The mounting surface of the printed circuit board 21 on which the NAND memory chip 22 and the controller chip 23 are mounted is sealed by a molding resin 31.

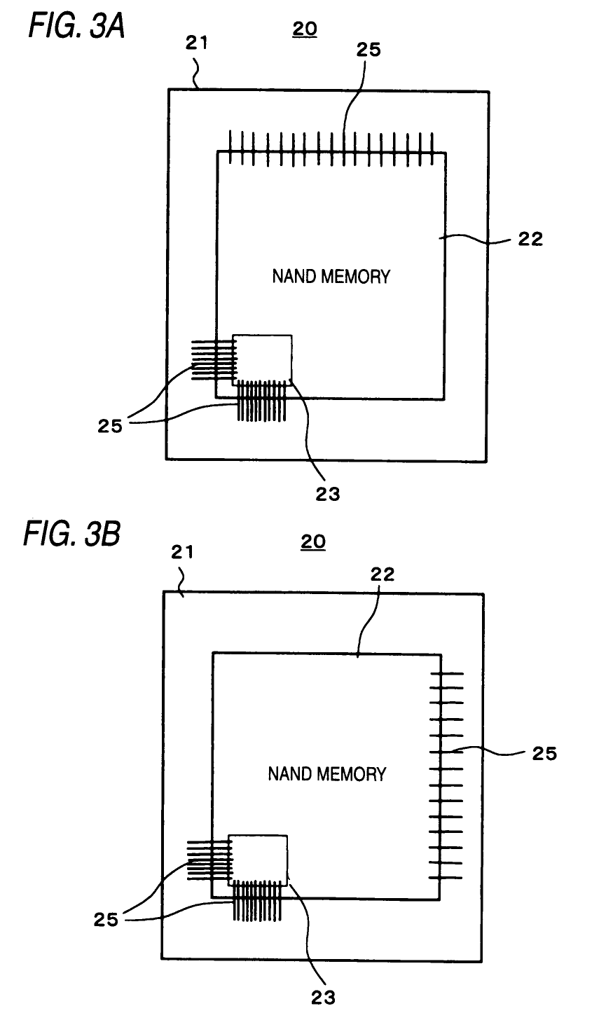

FIG. 3A is a plan view illustrating an example of a chip layout of the NAND flash memory 20 shown in FIG. 2 as viewed from the chip mounting surface. In the NAND memory chip 22 shown in FIG. 3A, plural pads are formed in a rectilinear shape in the upper end portion in the drawing. The plural pads are electrically connected to the plural pads disposed in the printed circuit board 21 by the bonding wires 25. In the controller chip 23, plural pads are formed in a rectilinear shape in the left end portion and the lower end portion in the drawing. The plural pads are electrically connected to the plural pads disposed in the printed circuit board 21 by the bonding wires 25. FIG. 3B is a plan view illustrating a connection state of the bonding wires 25 where the pad formation position in the NAND memory chip 22 is changed to the right end portion.

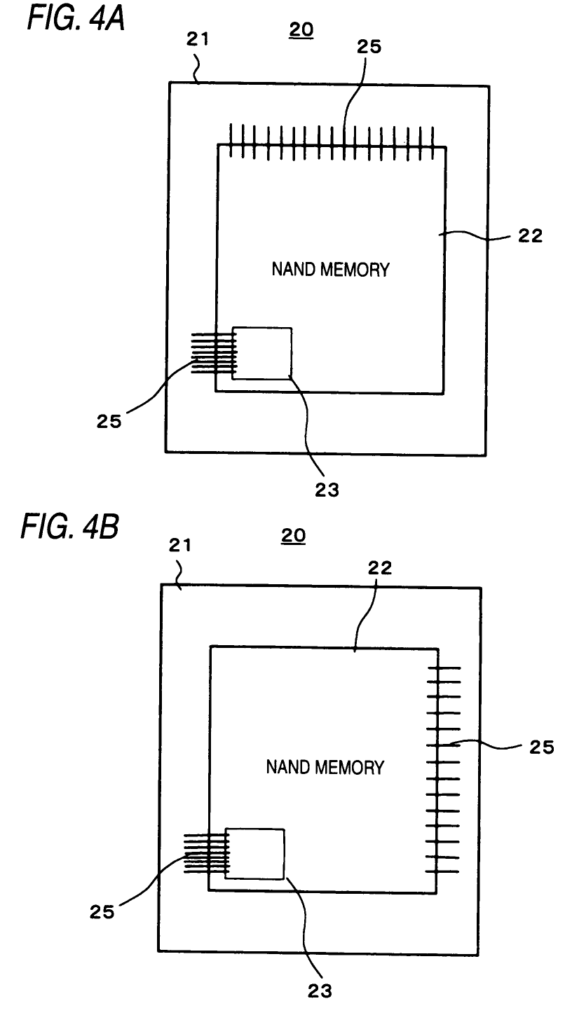

FIG. 4A is a plan view when the plural pads of the control chip 23 are formed in only the left end portion in the chip layout shown in FIG. 3A. FIG. 4B is a plan view when the plural pads of the control chip 23 are formed in only the left end portion in the chip layout shown in FIG. 3B.

In the chip layout of the NAND flash memory 1 shown in FIG. 1, the area of the cell array 3 increases with an increase in memory capacity and thus the bit lines connected in the cell array 3 are elongated. Accordingly, a tendency increases that a delay may increase at the time of transmitting and receiving data and power consumption may increase in the cell array 3. This tendency is true in the chip layouts shown in FIGS. 2 to 4.

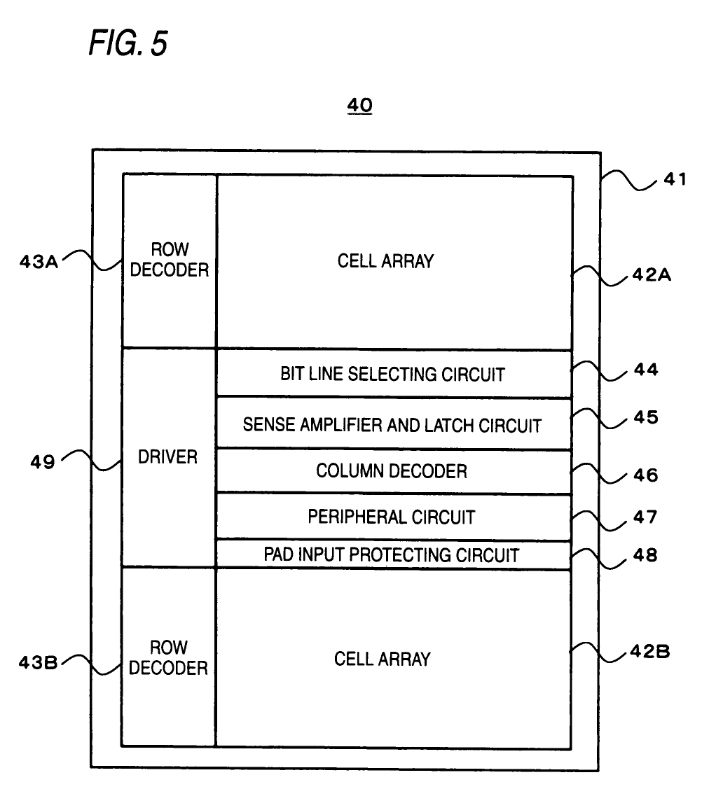

Therefore, as shown in FIG. 5, it can be considered that a bit line selecting circuit 44, a sense amplifier and latch circuit 45, a column decoder 46, a peripheral circuit 47, a pad input protecting circuit 48, and a driver 49 are disposed in the central portion of the semiconductor substrate 41.

FIG. 5 is a plan view illustrating another example of the chip layout of the NAND flash memory 40. In the NAND flash memory 40 shown in FIG. 5, two cell arrays 42A and 42B are disposed in an upper area and a lower area in the chip mounting surface of the semiconductor substrate 41 in the drawing. In this case, the bit line selecting circuit 44, the sense amplifier and latch circuit 45, the column decoder 46, the peripheral circuit 47, the pad input protecting circuit 48, and the driver 49 are disposed between the two cell arrays 42A and 42B. Row decoders 43A and 43B are disposed to correspond to the positions of the two cell arrays 42A and 42B. In this case, the bit line selecting circuit 44, the sense amplifier and latch circuit 45, the column decoder 46, the peripheral circuit 47, the pad input protecting circuit 48, and the driver 49 are shared by the two cell arrays 42A and 42B.

In this chip layout, since the bit lines in the cell arrays 42A and 42B as viewed from the bit line selecting circuit 44 are shorter by a half than those in the chip layouts shown in FIGS. 1 to 4, the load capacity of the bit lines may decrease. Accordingly, the delay also decreases at the time of transmitting and receiving data and the power consumption may decrease.

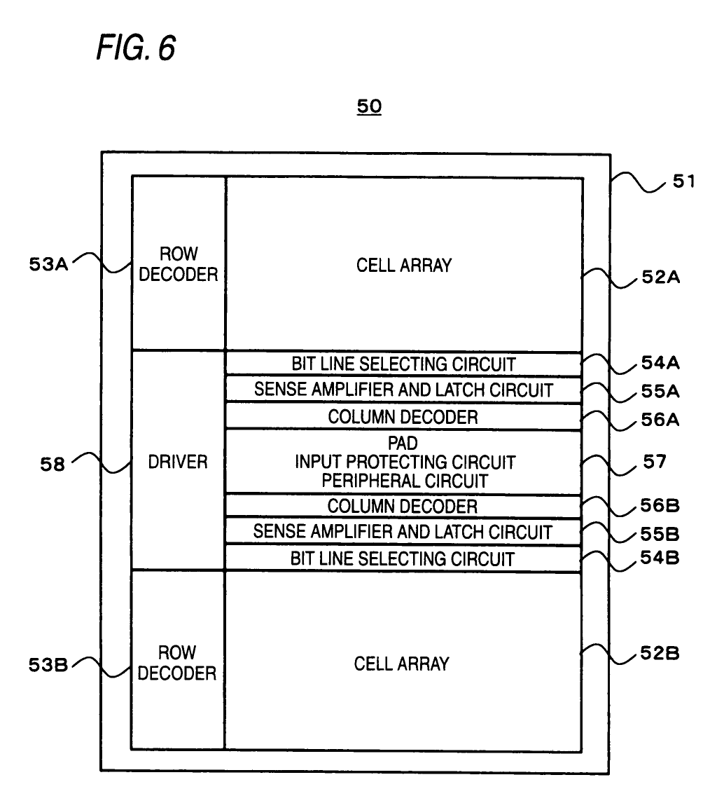

A chip layout shown in FIG. 6 can be considered as another example of the chip layout shown in FIG. 5. In FIG. 6, similarly to the chip layout shown in FIG. 5, bit line selecting circuits 54A and 54B, sense amplifier and latch circuits 55A and 55B, and column decoders 56A and 56B are divisionally disposed in two cell arrays 52A and 52B disposed on the semiconductor substrate 51. A pad input protecting circuit/peripheral circuit 57 is shared by the two cell arrays 52A and 52B.

In this chip layout, similarly to FIG. 5, since the bit lines in the cell arrays 52A and 52B as viewed from the bit line selecting circuits 54 are shorter by a half than those in the chip layouts shown in FIGS. 1 to 4, the load capacity of the bit lines may decrease. Accordingly, the delay may also decrease at the time of transmitting and receiving data and the power consumption may decrease. In the chip layout shown in FIG. 6, since wiring distances for power source or ground are averaged, the deviation in power supplied to the cell arrays 52A and 52B may decrease.

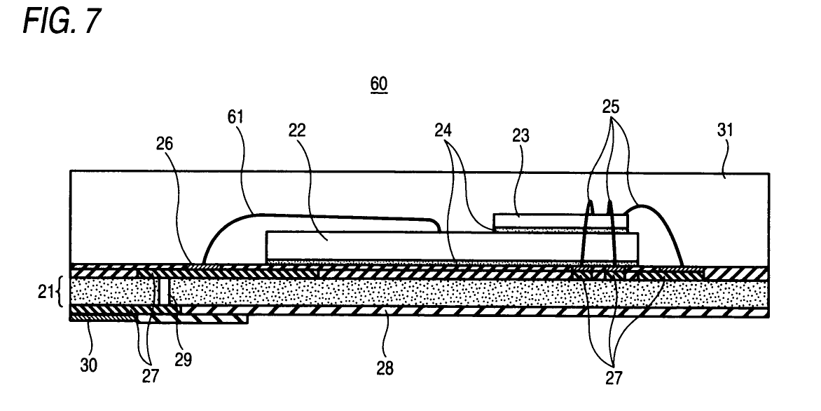

FIG. 7 is a sectional view illustrating an example of an inner configuration of a memory package 60 on which a NAND flash memory is mounted as a memory chip. FIG. 7 is different from the memory package 20 shown in FIG. 2, in that the pads of the NAND memory chip 22 are formed in the central portion of the top surface in the drawing. The pads of the NAND memory chip 22 and the bonding terminal plates 26 formed on the chip mounting surface of the printed circuit board 21 are electrically connected to each other by bonding wires 61. In FIG. 7, since the other elements are the same as shown in FIG. 2, they are referenced by the same reference numerals and description thereof is omitted.

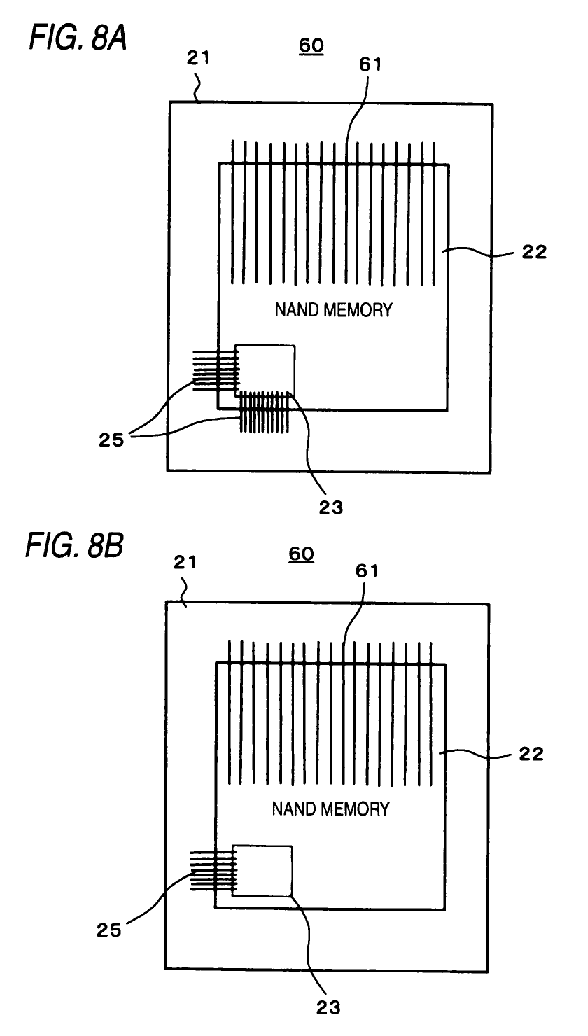

FIG. 8A is a plan view illustrating an example of the chip layout of the memory package 60 shown in FIG. 7 as viewed from the chip mounting surface. In the NAND memory chip 22 shown in FIG. 8A, plural pads are formed in a rectilinear shape in the central portion of the drawing. The plural pads are electrically connected to the plural pads disposed in the printed circuit board 21 by the bonding wires 61. Since the other elements of FIG. 8A are the same as shown in FIG. 3A, they are referenced by the same reference numerals and description thereof is omitted. FIG. 8B is a plan view illustrating a connection state of the bonding wires 25 where the pad formation position of the NAND memory chip 22 is changed to the right end portion.

In the chip layouts shown in FIGS. 7 and 8, the pad formation position is set to the central portion on the chip. In this case, the bonding wires 61 connecting the NAND memory chip 22 and the printed circuit board 21 are elongated and thus a phenomenon such as a wire drop may occur at the time of forming a mold.

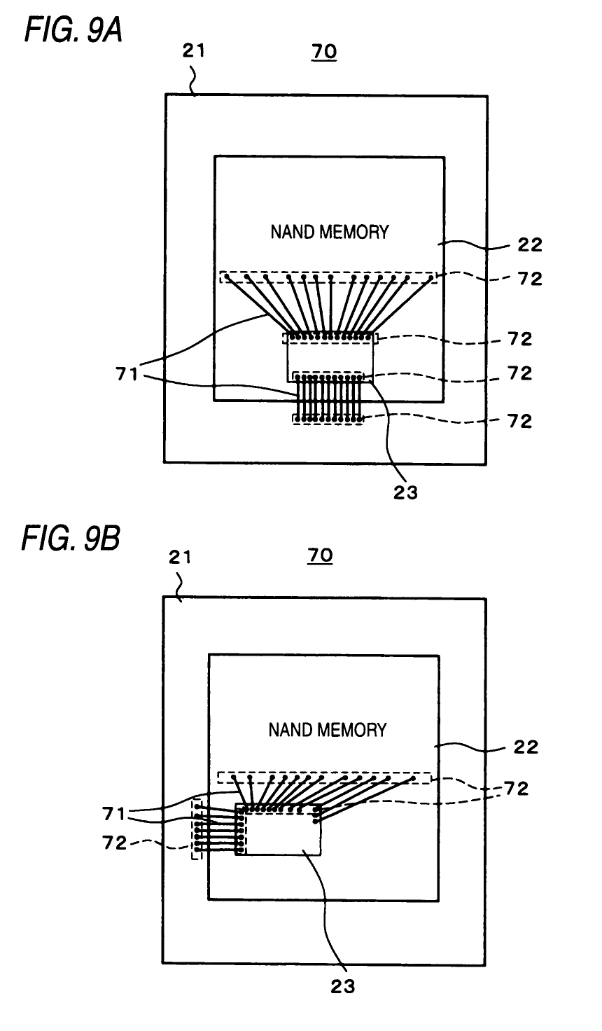

Accordingly, as shown in FIGS. 9A and 9B, a chip layout capable of reducing the lengths of the bonding wires connecting the chip and the board can be considered. In a NAND flash memory 70 shown in FIGS. 9A and 9B, the same elements as the NAND flash memory 20 shown in FIG. 3 are referenced by the same reference numerals.

In the NAND flash memory 70 shown in FIG. 9A, plural pads 72 are formed in a rectilinear shape in the central portion on one surface of the NAND memory chip 22 mounted on the chip mounting surface (on the board) of the printed circuit board 21. The controller chip 23 having an outer size smaller than that of the NAND memory chip 22 is mounted on a part other than the pad formation position on the one surface of the NAND memory chip 22. Plural pads 72 are formed in a rectilinear shape in the upper end portion and the lower end portion in the drawing, which are edges thereof, on the one surface of the controller chip 23. The plural pads 72 are formed in a rectilinear shape on the chip mounting surface of the printed circuit board 21 to correspond to the mounting position of the controller chip 23. The pads 72 are electrically connected by the bonding wires 71.

Accordingly, in the chip layout of the NAND flash memory 70 shown in FIG. 9A, the lengths of the bonding wires 71 connecting the printed circuit board 21, the NAND memory chip 22, and the controller chip 23 can be reduced to be smaller than those of the chip layouts shown in FIGS. 7 and 8. As a result, at the time of sealing the NAND flash memory 70 with a molding resin, it is possible to prevent the occurrence of the wire drop. In the NAND flash memory 70 shown in FIG. 9A, since the lengths of the bonding wires 71 can be reduced, the delay of signals due to the bonding wires 71 can be reduced, thereby improving the chip performance.

In the NAND flash memory 70 shown in FIG. 9B, the positions of the plural pads 72 formed on the one surface of the control chip 23 are different from those of the NAND flash memory 70 shown in FIG. 9A. In this case, the lengths of the bonding wires 71 connecting the printed circuit board 21, the NAND memory chip 22, and the controller chip 23 can be made to be smaller than those in the chip layouts shown in FIGS. 7 and 8. As a result, at the time of sealing the NAND flash memory 70 with a molding resin, it is possible to prevent the occurrence of the wire drop.

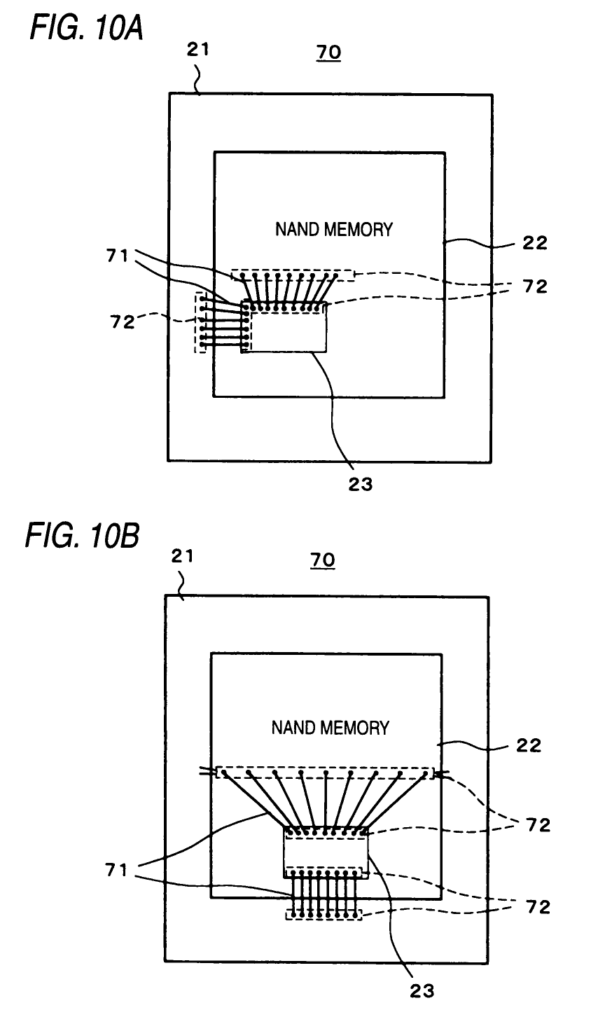

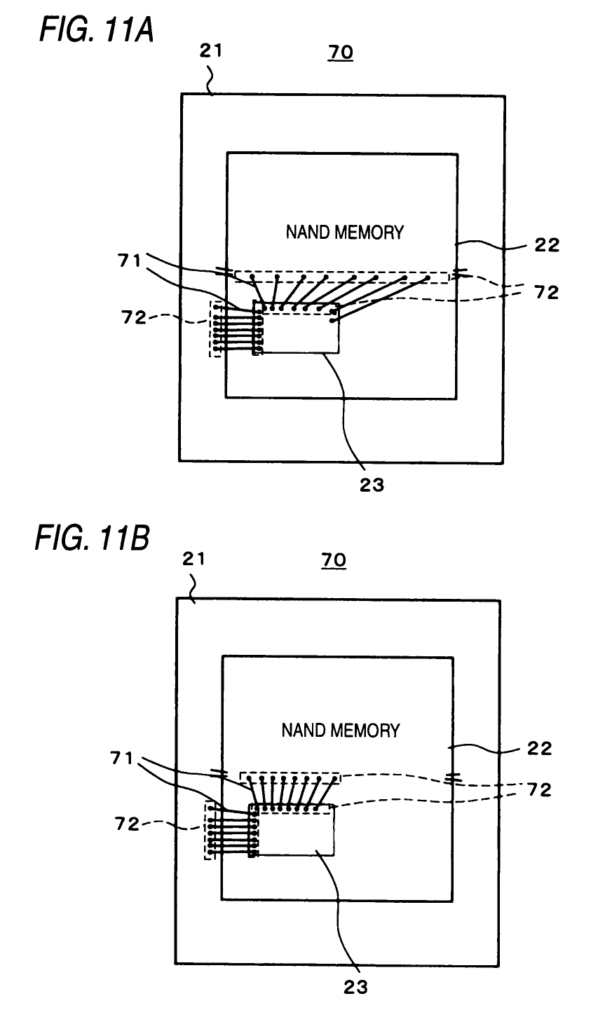

FIGS. 10A and 10B and FIGS. 11A and 11B are diagrams illustrating modified examples of the chip layouts shown in FIGS. 9A and 9B. In these chip layouts, the lengths of the bonding wires 71 connecting the printed circuit board 21, the NAND memory chip 22, and the controller chip 23 can be made to be smaller than those in the chip layouts shown in FIGS. 7 and 8. As a result, at the time of sealing the NAND flash memory 70 with a molding resin, it is possible to prevent the occurrence of the wire drop.

### Second Embodiment

In a second embodiment of the invention, an interconnection layer electrically connecting a memory chip and a board is formed in an upper layer of the memory chip mounted on the board.

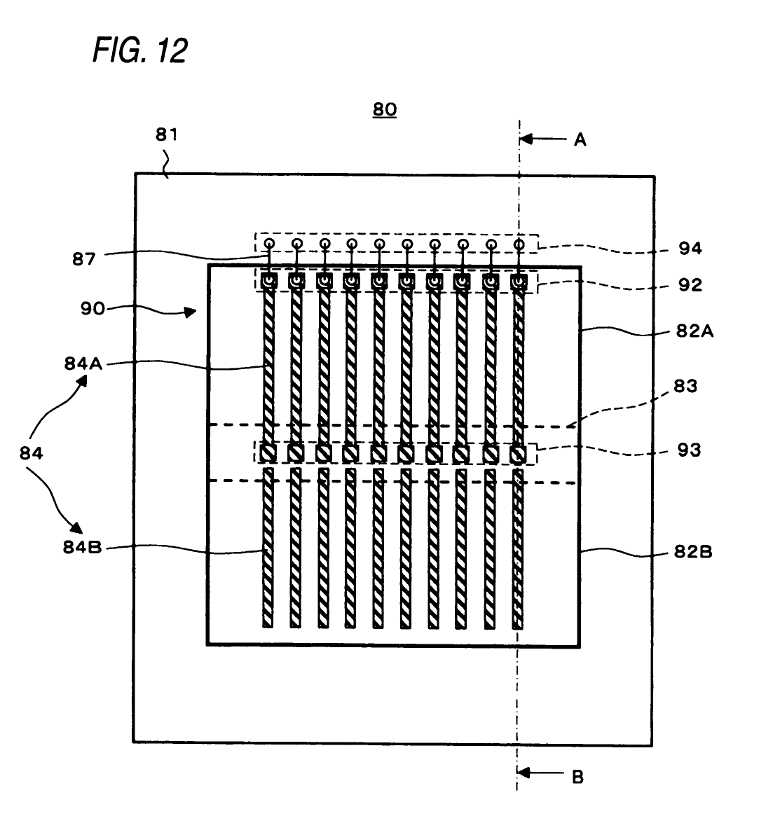

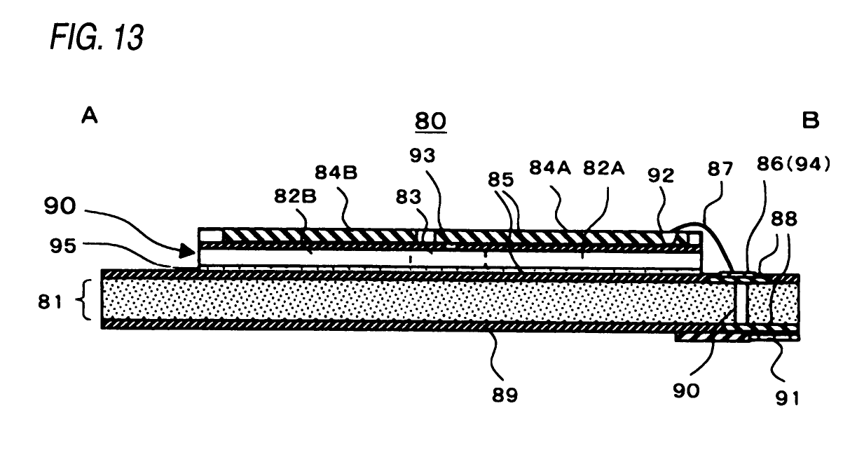

FIG. 12 is a plan view illustrating a chip layout of a NAND flash memory 80 according to a second embodiment of the invention. FIG. 13 is a sectional view taken along line A-B of the NAND flash memory 80 shown in FIG. 12. In the NAND flash memory 80 shown in FIGS. 12 and 13, a NAND memory chip 90 is mounted on a chip mounting surface of a printed circuit board 81. In the NAND memory chip 90, two memory cell arrays 82A (first memory cell array) and 82B (second memory cell array) are disposed in the upper side and the lower side of the drawings. In this case, a peripheral circuit 83 is disposed in the central portion between the two memory cell arrays 82A and 82B. The peripheral circuit 83 includes a control circuit controlling operations of the memory cell arrays 82A and 82B and a power supply circuit supplying power.

In the NAND flash memory 80 shown in FIG. 13, the NAND memory chip 90 is bonded to the chip mounting surface of the printed circuit board 81 by an adhesive 95. As shown in FIG. 13, an interconnection layer 84 is disposed in the upper layer of the NAND memory chip 90 with an insulating layer 85 interposed therebetween. As shown in FIGS. 12 and 13, plural contact plugs 92 are formed in a rectilinear shape in the upper side of the interconnection layer 84. As shown in FIGS. 12 and 13, plural contact plugs 93 electrically connected to the interconnection layer 84 are formed in a rectilinear shape in the insulating layer 85 on the peripheral circuit 83. As shown in FIG. 12, interconnection patterns 84A electrically connected the contact plugs 92 and the contact plugs 93 and dummy patterns 84B having the same shape as the interconnection patterns 84A are formed in the interconnection layer 84. On the chip mounting surface of the printing circuit board 81 shown in FIG. 12, plural pads 94 are formed in a rectilinear shape in the vicinity of the formation positions of the contact plugs 92 of the interconnection layer 84. The contact plugs 92 and the pads 94 formed on the printed circuit board 81 are electrically connected to each other by plural bonding wires 87.

In FIG. 13, a solder resist 89 is applied onto the chip mounting surface (top surface) and the chip non-mounting surface (bottom surface) of the printed circuit board 81 and bonding terminal plates 86 are formed therein. The bonding terminal plates 86 are electrically connected to the contact plugs 92 formed in the interconnection layer 84 by the bonding wires 87. That is, the bonding terminal plates 86 constitute the pads 94 shown in FIG. 12. External terminal plates 91 are formed in the right end portion of the printed circuit board 81 on the lower side of the drawing. Copper wires 88 are formed in the lower layer of the bonding terminal plates 86 and the upper layer of the external terminal plates 91. The copper wires 88 formed in the right side of the printed circuit board 81 in the drawing are connected with through-holes 90 to electrically connect the contact plugs 92 of the interconnection layer 84 to the external terminal plates 91.

As described above, in the NAND flash memory 80 according to the second embodiment, the peripheral circuit 83 is disposed in the central portion of the NAND memory chip 90 mounted on the chip mounting surface of the printed circuit board 81 and the interconnection layer 84 is formed in the upper layer of the NAND memory chip 90. Accordingly, since the lengths of the bit lines in the memory cell arrays 82A and 82B as viewed from the peripheral circuit 83 disposed in the central portion of the NAND memory chip 90 are smaller by a half than those in the chip layouts shown in FIGS. 1 to 4, it is possible to reduce the load capacity of the bit lines, thereby reducing the delay at the time of transmitting and receiving data and reducing the power consumption. Since the printed circuit board 81 and the NAND memory chip 90 are connected to each other by the interconnection layer 84, it is possible to reduce the lengths of the bonding wires 87. Accordingly, it is possible to reduce the signal delay due to the bonding wires 87, thereby improving the chip performance.

### Third Embodiment

In a third embodiment of the invention, a row decoder is disposed in a central portion of a substrate and a peripheral circuit and a pad input protecting circuit are disposed in the row direction of the substrate in the chip layout.

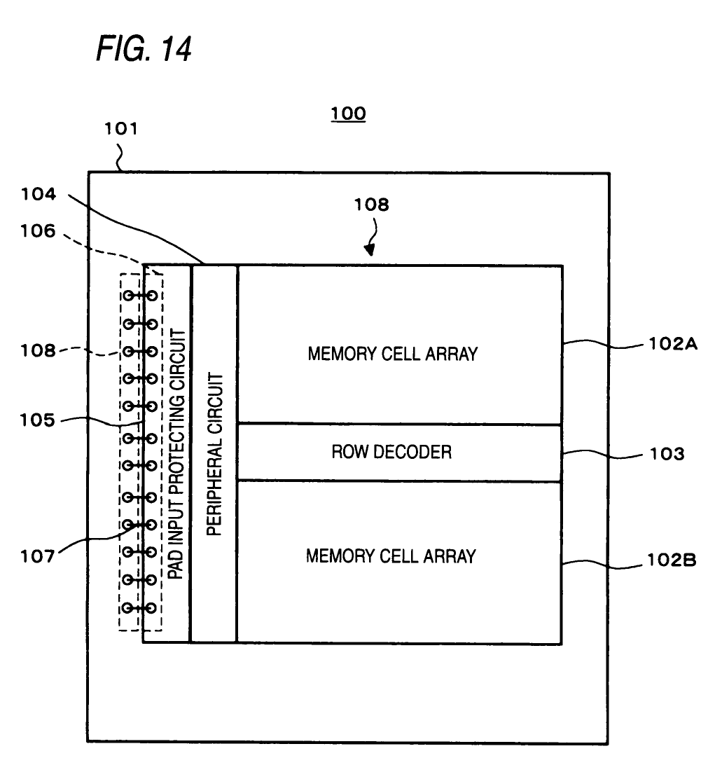

FIG. 14 is a plan view illustrating a chip layout of a NAND flash memory 100 according to the third embodiment of the invention. In the NAND flash memory 100 shown in FIG. 14, a NAND memory chip 108 is mounted on a chip mounting surface of a printed circuit board 101. In FIG. 14, two memory cell arrays 102A (first memory cell array) and 102B (second memory cell array) are disposed in an upper side and a lower side of the drawing. In this case, a row decoder 103 (decoder circuit) is disposed in the central portion between the two memory cell arrays 102A and 102B. In the left side of the chip mounting surface of the printed circuit board 101 in the drawing, a peripheral circuit 104 and a pad input protecting circuit 105 are mounted along the left edge of the mounting positions of the memory cell arrays 102A and 102B and the row decoder 103. The peripheral circuit 104 includes a control circuit controlling operations of the memory cell arrays 102A and 102B and a power supply circuit supplying power.

Plural contact plugs 106 are formed in a rectilinear shape in the pad input protecting circuit 105 along the left edge in the drawing. The pad input protecting circuit 105 includes input protecting circuits (not shown) for the memory cell arrays 102A and 102B and the row decoder 103. On the chip mounting surface of the printed circuit board 101 shown in FIG. 14, plural pads 108 are formed in a rectilinear shape in the vicinity of the formation positions of the contact plugs 106. The contact plugs 106 and the pads 108 are electrically connected by plural bonding wires 107.

As described above, in the NAND flash memory 100 according to the third embodiment of the invention, the row decoder 103 is disposed between the memory cell arrays 102A and 102B, the peripheral circuit 104 and the pad input protecting circuit 105 are disposed on the left edge of the printed circuit board 101, and the contact plugs 106 and the pads 108 are formed along the disposed position of the pad input protecting circuit 104. Accordingly, the lengths of the word lines in the memory cell arrays 102A and 102B as viewed from the row decoder 103 can be reduced and the load capacity of the word lines can be reduced, thereby reducing the delay at the time of transmitting and receiving data and reducing the power consumption. Since the pads 108 are formed on the printed circuit board 101 along the contact plugs 106 formed in the pad input protecting circuit 104, it is possible to further reduce the lengths of the bonding wires 107 and to reduce the signal delay due to the bonding wires 107, thereby improving the chip performance.

### Fourth Embodiment

In a fourth embodiment of the invention, plural NAND memory chips are mounted on a board using a flip chip mounting method.

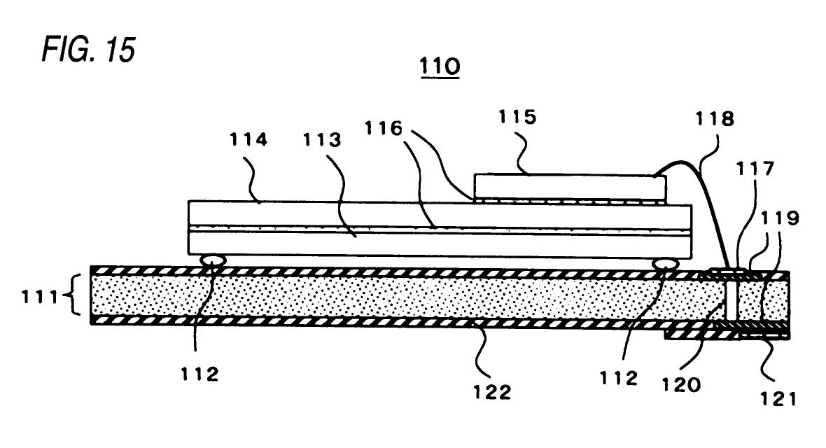

FIG. 15 is a sectional view illustrating a chip layout of a NAND flash memory 110 according to the fourth embodiment of the invention. In the NAND flash memory 110 shown in FIG. 15, plural bumps 112 are arranged in an array on a chip mounting surface of a printed circuit board 111. Reference numeral 113 represents a NAND memory chip in which plural pads (not shown) are formed in an array on a surface opposed to the chip mounting surface of the printed circuit board 111 to correspond to the formation positions of the bumps 112. Accordingly, the NAND memory chip 113 is mounted to correspond to the arrangement positions of the bumps 112 on the chip mounting surface of the printed circuit board 111. A NAND memory chip 114 is bonded to the top surface of the NAND memory chip 113 by an adhesive 116. A controller chip 115 is bonded to the top surface of the NAND memory chip 114 by an adhesive 116.

In FIG. 15, a solder resist 122 is applied to the chip mounting surface (top surface) and a chip non-mounting surface (bottom surface) of the printed circuit board 111 and bonding terminal plates 117 are also formed therein. The bonding terminal plates 117 are electrically connected to pads (not shown) formed on the surface of the controller chip 115 by bonding wires 118. External terminal plates 121 are formed in the right end portion of the bottom surface of the printed circuit board 111 in the drawing. Copper wires 119 are formed in the lower layer of the bonding terminal plates 117 and the upper layer of the external terminal plates 121. The copper wires 119 formed on the right side of the printed circuit board 111 in the drawing are connected to each other through through-holes 120 to electrically connect the pads of the controller chip 115 to the external terminal plates 121.

As described above, in the NAND flash memory 110 according to the fourth embodiment of the invention, the NAND memory chip 113 is mounted on the printed circuit board 111 using the flip chip mounting method. Accordingly, the printed circuit board 111 and the NAND memory chip 113 can be directly connected to each other and thus it is possible to reduce the delay at the time of transmitting and receiving data and to reduce the power consumption, compared with the connection using the bonding wires.

### Fifth Embodiment

In a fifth embodiment of the invention, plural NAND memory chips are mounted in multiple layers and interconnection layers electrically connecting the chips and the board are formed in upper layers of the chips.

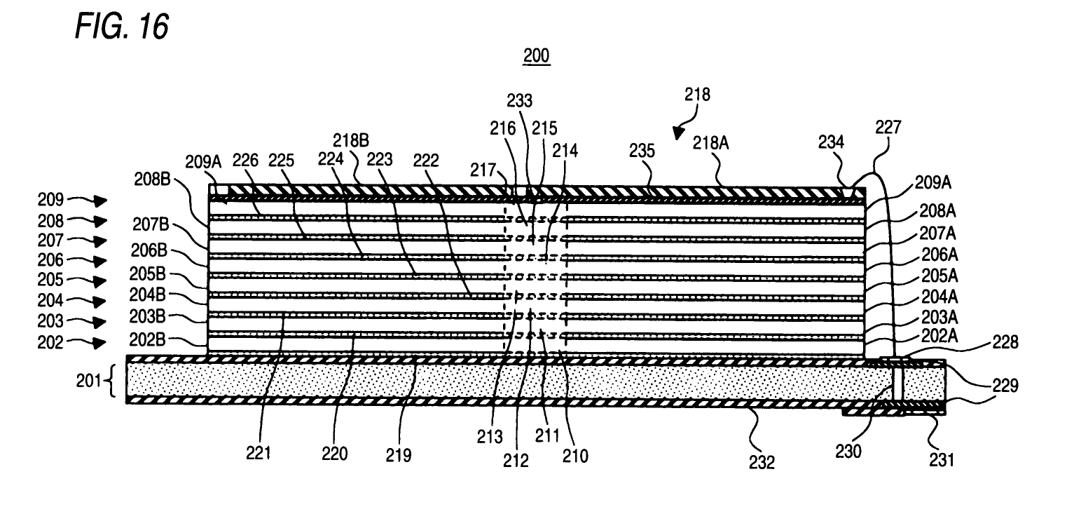

FIG. 16 is a sectional view illustrating a chip layout of a NAND flash memory 200 according to the fifth embodiment of the invention. In the NAND flash memory 200 shown in FIG. 16, NAND memory chips 202 to 209 are stacked on a chip mounting surface of a printed circuit board 201. In the respective NAND memory chips 202 to 209, memory cell arrays 202A to 209A and 202B to 209B are disposed in the left side and the right side of the drawing. Peripheral circuits 210 to 217 are disposed in central portions between the memory cell arrays 202A to 209A and 202B to 209B of the NAND memory chips 202 to 209. The respective peripheral circuits 210 to 217 include a control circuit controlling operations of both memory cell arrays 202A and 202B, 203A and 203B, 204A and 204B, 205A and 205B, 206A and 206B, 207A and 207B, 208A and 208B, and 209A and 209B stacked in the same layer and a power supply circuit supplying power.

In the NAND flash memory 200 shown in FIG. 16, the NAND memory chips 202 to 209 are stacked on the chip mounting surface of the printed circuit board 201 and are bonded to each other by adhesives 219 to 226 every layer. As shown in FIG. 16, an interconnection layer 218 is formed in the upper layer of the NAND memory chip 209 with an insulating layer 235 interposed therebetween. Similarly to the interconnection layer 84 shown in FIG. 12, plural contact plugs 234 are formed in a rectilinear shape (in the depth direction in the drawing) on the upper edge (peripheral portion) of the interconnection layer 218. Similarly to the insulating layer 85 in the upper layer of the peripheral circuit 83 shown in FIG. 12, plural contact plugs 233 electrically connected to the interconnection layer 218 are formed in a rectilinear shape (in the depth direction in the drawing) in the insulating layer 235 in the upper layer of the peripheral circuit 217. As shown in FIG. 16, interconnection patterns 218A electrically connecting the contact plugs 233 to the contact plugs 234 and dummy patterns 218B having the same shape as the interconnection patterns 218A are formed in the interconnection layer 218. Similarly to the interconnection layer 84 and the printed circuit board 81 shown in FIG. 12, plural pads 228 are formed in a rectilinear shape (in the depth direction in the drawing) on the chip mounting surface of the printed circuit board 201 in the vicinity of the formation position of the contact plugs 234 of the interconnection layer 218. The contact plugs 234 formed in the end portion of the interconnection patterns 218A of the interconnection layer 218 and the pads 228 formed in the printed circuit board 201 are electrically connected to each other by plural bonding wires 227.

In FIG. 16, a solder resist 232 is applied onto the chip mounting surface (top surface) and the chip non-mounting surface (bottom surface) of the printed circuit board 201 and bonding terminal plates 228 are formed therein. The bonding terminal plates 228 are electrically connected to the contact plugs 234 formed at the end portions of the interconnection patterns 218A by the bonding wires 227. That is, the bonding terminal plates 228 constitute the pads 228 of the printed circuit board 201. External terminal plates 231 are formed in the right end portion of the printed circuit board 201 on the lower side of the drawing. Copper wires 229 are formed in the lower layer of the bonding terminal plates 228 and the upper layer of the external terminal plates 231. The copper wires 229 formed in the right side of the printed circuit board 201 in the drawing are connected with through-holes 230 to electrically connect the contact plugs 234 formed in the end portions of the interconnection patterns 218A and the external terminal plates 231.

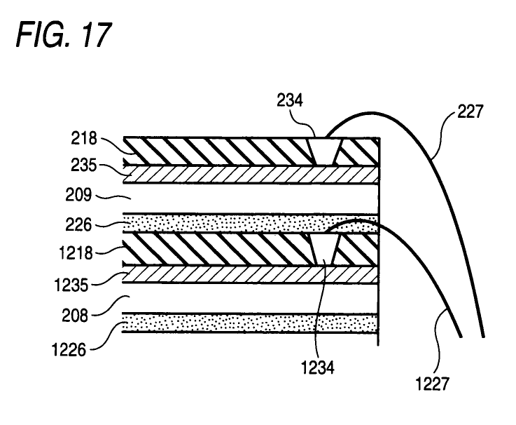

FIG. 17 is an enlarged sectional view showing the contact plug of FIG. 16 and its periphery in detail. As described above, the bonding wires 227 are electrically connected to the contact plug 234 formed in the end portion of the interconnection patterns 218A. An insulation layer 1235 and the wiring layer 1218 are omitted in FIG. 16, but the insulation layer 1235 and the wiring layer 1218 are formed between the NAND memory chips 208 and 209. The wiring layer 1218 includes a contact plug 1234 and a bonding wire 1227 is connected to the contact plug 1234. A signal line of the NAND memory chip 208 is led out by forming the adhesive 226 after connecting the bonding wire 1227 to the contact plug 1234. Regarding NAND memory chips 207, 206, 205, 204, 203, those interlayers have the same structure as the insulation layer 1235 and the wiring layer 1218. A plurality of bonding wires is connected to the contact plugs formed in the interlayers.

As described above, in the NAND flash memory 200 according to the fifth embodiment, the peripheral circuits 210 to 217 are disposed in the central portions of the NAND memory chips 202 to 209 stacked on the chip mounting surface of the printed circuit board 201 and the interconnection layer 218 is formed in the upper layer of the NAND memory chip 209 as the uppermost layer. Accordingly, since the lengths of the bit lines in the NAND memory chips 202 to 209 as viewed from the peripheral circuits 210 to 217 are smaller by a half than those in the chip layouts shown in FIGS. 1 to 4, it is possible to reduce the load capacity of the bit lines, thereby reducing the delay and reducing the power consumption at the time of transmitting and receiving data. Since the printed circuit board 201 and the chips are connected to each other by the interconnection layer 218, it is possible to reduce the lengths of the bonding wires 227. Accordingly, it is possible to reduce the signal delay due to the bonding wires 227, thereby improving the chip performance.

As described with reference to the above embodiments, there is provided a semiconductor device in which plural memory chips and a controller chip are mounted on a substrate and which can implement a chip layout capable of shortening an interconnection between chips to improve performance thereof.

According to the above embodiments, it is possible to provide a semiconductor device in which plural memory chips and a controller chip are mounted on a substrate and which can implement a chip layout capable of shortening an interconnection between chips to improve performance thereof.

What is claimed is:

1. A semiconductor device comprising:
a semiconductor substrate;
a memory chip disposed on the semiconductor substrate,
the memory chip including:
a first face that is not opposed to the semiconductor substrate; and
a plurality of first pads disposed on the first face so that the first pads are aligned along a virtual line passing at a central portion on the first face;
a controller chip disposed on the first face not to cover the first pads, the controller chip including:
a second face that is not opposed to the first face; and
a plurality of second pads disposed on the second face so that the second pads are aligned along at least one side of the second face; and
a plurality of metal wires electrically connecting the first pads and the second pads.

2. A semiconductor device comprising:
a semiconductor substrate;
a memory chip disposed on the semiconductor substrate,
the memory chip including:
a first memory cell array;
a second memory cell array; and
a peripheral circuit formed between the first memory cell array and the second memory cell array, the peripheral circuit being configured to control the first memory cell and the second memory cell;
a plurality of first pads formed on the semiconductor substrate so that the first pads are aligned along the first memory cell array;
a plurality of second pads formed on the memory chip so that the second pads are aligned along the first pads;
a wiring layer formed on the memory chip, the wiring layer having a wiring pattern to electrically connect the second pads and the peripheral circuit; and
a plurality of metal wires electrically connecting the first pads and the second pads.

3. A semiconductor device comprising:
a semiconductor substrate;
a memory chip disposed on the semiconductor substrate,
the memory chip including:
a first memory cell array;
a second memory cell array;
a decoder circuit formed between the first memory cell array and the second memory cell array, the decoder circuit includes peripheral circuit for controlling the first memory cell and the second memory cell; and
an input circuit disposed along the decoder circuit, the first memory cell, and the second memory cell, the input circuit controlling an input signal to the decoder circuit, the first memory cell, and the second memory cell;
a plurality of pads formed on the semiconductor substrate so that the pads are aligned along the input circuit; and
a plurality of metal wires electrically connecting the pads and the input circuit.

4. A semiconductor device comprising:
a printed circuit board having a connection portion formed on a mounting face of the printed circuit;
a plurality of bumps disposed on the mounting surface;
a first memory chip having a first face and a second face, the first face being bonded to the bumps;
a second memory chip having a third face and a fourth face, the third face being bonded to the second face;
a controller chip having a fifth face and a sixth face, the fifth face being bonded to the fourth face; and
a metal wire electrically connecting the connection portion and the controller chip.

5. The semiconductor device according to claim 1, wherein the controller chip further includes a plurality of third pads on the second face, the third pads being aligned along one side of the second face,
the semiconductor substrate includes a plurality of fourth pads on the semiconductor substrate, the fourth pads being aligned along one side of the first face corresponding to the one side of the second face, and
the third pads are electrically connected to the fourth pads by second metal wires.

6. The semiconductor device according to claim 2, wherein the wiring layer further includes a dummy wiring pattern extending from the peripheral circuit to an opposite side of the wiring pattern.

7. The semiconductor device according to claim 4, wherein the first face is an opposite face of the second face,
the third face is an opposite face of the fourth face, and
the fifth face is an opposite face of the sixth face.

8. The semiconductor device according to claim 4, wherein the sixth face includes a pad, and
the metal wire electrically connecting the connection portion and the pad.

9. The semiconductor device according to claim 1, wherein the memory chip includes a nonvolatile memory chip.

10. The semiconductor device according to claim 2, wherein the memory chip includes a nonvolatile memory chip.

11. The semiconductor device according to claim 3, wherein the memory chip includes a nonvolatile memory chip.

12. The semiconductor device according to claim 4, wherein the first memory chip includes a nonvolatile memory chip, and
the second memory chip includes a nonvolatile memory chip.
